(19) United States
(12) Patent Application Publication
(10) Pub. No.: US 2010/0102459 A1
(43) Pub. Date: Apr. 29, 2010

(54) SEMICONDUCTOR DEVICE

(76) Inventor: Motoaki SATOU, Kyoto (JP)

Correspondence Address: MCDERMOTT WILL & EMERY LLP, 600 13TH STREET, NW, WASHINGTON, DC, 20005-3096, US

(21) Appl. No.: 12/471,773

(22) Filed: May 26, 2009

(30) Foreign Application Priority Data
Oct. 29, 2008 (JP) 2008-278088
Mar. 25, 2009 (JP) 2009-073699

(51) Int. Cl. H01L 23/485

(52) U.S. Cl. 257/783; 257/E23.02

(57) ABSTRACT

The semiconductor device includes: a semiconductor chip; a die pad for holding the semiconductor chip; a lead; and a sealing resin material for sealing the semiconductor chip, the die pad and an inner portion of the lead. The die pad has an upset portion protruding upward to form a flat face smaller in area than the semiconductor chip, and the portion of the die pad excluding the upset portion is covered with a buffer resin material smaller in elasticity than the sealing resin material.

### CROSS-REFERENCE TO RELATED APPLICATIONS

This application claims priority under 35 U.S.C. §119 on Patent Application No. 2008-278088 filed in Japan on Oct. 29, 2008 and Patent Application No. 2009-73699 filed in Japan on Mar. 25, 2009, the entire contents of which are hereby incorporated by reference.

### BACKGROUND OF THE INVENTION

The present invention relates to a semiconductor device including at least one semiconductor chip sealed in a package.

At present, a standardized surface-mount type semiconductor package is configured as follows: a semiconductor chip is fixed to a die pad of a lead frame made of a cupper (Cu) alloy or an iron-nickel (Fe—Ni) alloy by die bonding, a bonding pad (electrode pad) of the semiconductor chip and the end of each lead of the lead frame are wire-bonded to each other with a metal wire made of gold (Au) and the like, and the resultant chip is resin-molded using a mold having a predetermined shape.

In recent years, with the progression of large scale integration (LSI) devices, implementing a memory part and a logic part in one chip, or implementing a digital part and an analog part in one chip has been proceeding at a rapid pace. As a result, low cost competition in the market has been further intensified. Nowadays, therefore, simply integrating such functions into one chip and subjecting the chip to a diffusion process to attain one-chip implementation is no more advantageous in the market competition.

In view of the above, it is becoming higher in the probability of making a profit to select an optimum chip form and seal a plurality of semiconductor chips into one package than to integrate functions into one chip under one-chip implementation. An example of the former case is a multi-chip semiconductor device.

FIG. 8 shows a cross-sectional configuration of a major part of a conventional multi-chip semiconductor device having a plurality of semiconductor chips stacked one on another. As shown in FIG. 8, the multi-chip semiconductor device includes: a plurality of leads 101 of a lead frame; a heat dissipation plate/die pad 102 placed in a region surrounded by the plurality of leads 101; and first and second semiconductor chips 103A and 103B attached to the main face of the heat dissipation plate/die pad 102 via an adhesive paste 104. The first and second semiconductor chips 103A and 103B are attached to each other via an adhesive sheet 105 and the like. Each of the semiconductor chips 103A and 103B is connected to the ends of inner portions of the leads 101 via metal wires 106. The heat dissipation plate/die pad 102, the semiconductor chips 103A and 103B, the inner portions of the leads 101 and the metal wires 106 are molded with a sealing resin material 107.

### SUMMARY OF THE INVENTION

The conventional multi-chip semiconductor device described above, which includes a plurality of semiconductor chips stacked one upon another, is large in the number of signal buses and power consumption. Hence, efficient conduction of heat dissipated from the semiconductor chips is necessary to prevent occurrence of a malfunction and reduction in reliability due to a rise of the junction temperature.

As described in Japanese Laid-Open Patent Publication No. 2003-092379, a technique of attaching a metal plate to the back face of a semiconductor chip, for example, over a wide range has been conventionally adopted for increasing the heat dissipation effect. However, since the coefficient of linear expansion is greatly different between the metal plate and a resin material, the chip may have warping and internal stress that may impede the layered structure high in the flatness between a plurality of semiconductor chips, causing a problem that the reliability of the semiconductor device decreases.

To overcome the problem described above, an object of the present invention is to provide a semiconductor device packaged with a sealing resin material in which the thermal stress between component materials is dispersed and warping of semiconductor chips is suppressed to enhance the flatness between the chips, to thereby improve the reliability.

To attain the above object, the semiconductor device of the present invention is configured as follows. An upset portion that is a protrusion having a flat top face is formed as part of a die pad, to allow a semiconductor chip to be fixed to the top face of the upset portion. Also, the portion surrounding the upset portion of the die pad is covered with a resin material smaller in elasticity than a sealing resin material, or otherwise a groove protruding from the back face of the die pad is formed around the upset portion of the die pad.

Specifically, the first semiconductor device of the present invention includes: a semiconductor chip; a die pad for holding the semiconductor chip; a lead; and a sealing resin material for sealing the semiconductor chip, the die pad and an inner portion of the lead, wherein the die pad has an upset portion protruding upward to form a flat face smaller in area than the semiconductor chip, and the portion of the die pad excluding the upset portion is covered with a buffer resin material smaller in elasticity than the sealing resin material.

According to the first semiconductor device of the present invention, the die pad has the upset portion protruding upward to form a flat face small in area than the semiconductor chip, and the semiconductor chip is held only with the upset portion. Hence, warping due to the stress with chip attachment during fabrication can be reduced, ensuring the flatness of the semiconductor chip. Moreover, since the portion of the die pad excluding the upset portion is covered with the buffer resin material small in elasticity than the sealing resin material, the difference in the coefficient of linear expansion between the die pad generally made of a metal and the sealing resin material can be absorbed and relieved. Therefore, it is possible to prevent occurrence of peeling off of the sealing resin material from the die pad due to the stress with the heat history during fabrication and the heat during packaging. Hence, the heat dissipation and reliability can be improved.

The second semiconductor device of the present invention includes: a semiconductor chip; a die pad for holding the semiconductor chip; a lead; and a sealing resin material for sealing the semiconductor chip, the die pad and an inner portion of the lead, wherein the die pad has an upset portion protruding upward to form a flat face smaller in area than the semiconductor chip and a down-set portion essentially composed of at least one groove protruding downward from the bottom face of the die pad.

According to the second semiconductor device of the present invention, the die pad has the upset portion protruding upward to form a flat face small in area than the semiconductor chip, and the semiconductor chip is held only with the upset portion. Hence, warping due to the stress with chip attachment during fabrication can be reduced, ensuring the flatness of semiconductor chips stacked. Moreover, the die pad also has a down-set portion essentially composed of at least one groove protruding from the bottom face of the die pad formed to surround the upset portion. With the upset portion and the down-set portion formed in the die pad giving the projection/depression shape, the anchor effect can be provided. Therefore, it is possible to prevent occurrence of peeling off of the sealing resin material from the die pad due to the stress with the heat history during fabrication and the heat during packaging. Hence, the heat dissipation and reliability can be improved.

In the second semiconductor device, the down-set portion of the die pad may be formed at a position under the semiconductor chip.

With the above configuration, the space between the semiconductor chip and the die pad can be easily filled with the sealing resin material, and hence the strength of the package improves.

In the second semiconductor device, the upset portion and the down-set portion may be formed by press shearing and have a side face vertical to the main face of the die pad.

With the above configuration, the surface area of the die pad increases, and hence the heat dissipation further improves.

In the first or second semiconductor device, the semiconductor chip may include a plurality of semiconductor chips attached to each other.

The above configuration can further ensure stacking of the plurality of semiconductor chips one on another.

In the first or second semiconductor device, preferably, the upset portion and the semiconductor chip are attached to each other with an adhesive, and the adhesive is a paste resin material.

The above configuration can secure the heat conductivity between the upset portion of the die pad and the semiconductor chip.

In the first or second semiconductor device, the plan area of the die pad may be greater than the plan area of the semiconductor chip.

The above configuration further improves the heat dissipation with the die pad.

In the first or second semiconductor device, the shape of the upset portion in plan may be tetragonal.

With the above configuration, the difference in area between the die pad and the semiconductor chip decreases, and hence reduction in the rigidity of the semiconductor chip can be compensated. This is because when the sealing resin material and the semiconductor chip are relatively thin, the die pad is dominant for the rigidity of the semiconductor device itself. In this case, pressing under ultrasonic vibration during wire bonding may not be transferred sufficiently due to reduction in the rigidity of the semiconductor chip, for example, and hence a good bonded state of the alloy layers with wires may not be obtained.

In the first or second semiconductor device, the shape of the upset portion in plan may be circular.

With the above configuration, the difference in area between the die pad and the semiconductor chip increases, and hence since the area of the contact portion via the adhesive that is the stress generation source for interface fracture can be reduced, generation of the stress can be reduced. This is because when the sealing resin material and the semiconductor chip are relatively thick, the thicknesses of the semiconductor chip and the sealing resin material are dominant for the rigidity of the semiconductor device itself. In this case, warping does not occur with the stress at the contact portion between the upset portion as the inner portion of the die pad and the semiconductor chip attached together with the adhesive, which tends to expand or contract during temperature cycling testing and reflowing. Instead, interface fracture may occur with high probability. It will be effective to make the contact area via the adhesive paste further small as long as a predetermined adhesion strength can be guaranteed.

In the first semiconductor device, the buffer resin material may include grains made of an inorganic material or a metal high in thermal conductivity added therein.

The above configuration improves the heat dissipation of the buffer resin material.

As described above, in a chip-stacked semiconductor device in which semiconductor chips are stacked one on another on a metal plate (die pad) high in heat conductivity for obtaining high heat dissipation performance, there is a high risk, caused by the difference in the coefficient of linear expansion depending the component materials and heat, that the semiconductor chips and the metal plate may warp and the sealing resin material may peel off from these components due to failure in balancing of the internal stress.

According to the present invention, the region of the metal plate, which also serves as the heat dissipation plate, excluding the contact portion thereof with the semiconductor chip is coated with a low-elastic resin material as a buffer, or otherwise a cross-sectional structure high in anchor effect is adopted for the metal plate, and yet an area large enough to ensure heat conduction is guaranteed.

Specifically, a step portion is provided in the center of the metal plate, to have a flat face smaller in area than the chip size. With this, warping due to the stress with chip attachment in the fabrication process can be reduced, and the flatness of the top face of the semiconductor chip can be guaranteed. In this case, however, a gap is formed between the semiconductor chip and the peripheral portion of the metal plate, and hence a layered structure with a sealing resin material interposed between layers is given at the final stage, increasing the difference between a high cohesion layer and a low cohesion layer and the difference in linear expansion. To prevent this problem, according to the present invention, the surface of the metal plate made of a material large in the coefficient of linear expansion and small in the difference in cohesion from the resin material is coated with a buffer resin material as a buffer layer. Otherwise, a projection/depression shape is given to the peripheral portion of the metal plate to provide the anchor effect. In this way, the semiconductor device is made durable against the failure in balancing of the internal stress and the high-temperature vapor pressure after moisture absorption.

As described above, according to the semiconductor device of the present invention, packaged with a sealing resin material, the thermal stress between component materials is dispersed and warping of semiconductor chips is suppressed. As a result, the flatness between the chips improves, and hence the reliability can be greatly improved.

### BRIEF DESCRIPTION OF THE DRAWINGS

FIG. 1 is a diagrammatic cross-sectional view of a semiconductor device of example Embodiment 1.

FIG. 2A is a plan view of a die pad of the semiconductor device of example Embodiment 1. FIG. 2B is a cross-sectional view taken along line IIb-IIb in FIG. 2A.

FIG. 3A is a plan view of a die pad of a semiconductor device of a first alteration of example Embodiment 1. FIG. 3B is a cross-sectional view taken along line IIIb-IIIb in FIG. 3A. FIG. 3C is a cross-sectional view of a die pad of a semiconductor device of a second alteration of example Embodiment 1. FIG. 3D is a cross-sectional view of a die pad of a semiconductor device of a third alteration of example Embodiment 1. FIG. 3E is a cross-sectional view of a die pad of a semiconductor device of a fourth alteration of example Embodiment 1.

FIG. 4 is a partial cross-sectional view showing a buffer resin material provided on a die pad of a semiconductor device of a fifth alteration of example Embodiment 1.

FIG. 5 is a diagrammatic cross-sectional view of a semiconductor device of example Embodiment 2.

FIG. 6A is a plan view of a die pad of the semiconductor device of example Embodiment 2. FIG. 6B is a cross-sectional view taken along line VIb-VIb in FIG. 6A.

FIG. 7A is a plan view of a die pad of a semiconductor device of an alteration of example Embodiment 2. FIG. 7B is a cross-sectional view taken along line VIIb-VIIb in FIG. 7A.

FIG. 8 is a diagrammatic cross-sectional view of a conventional multi-chip semiconductor device.

### DESCRIPTION OF THE PREFERRED EMBODIMENTS

### Embodiment 1

Example Embodiment 1 will be described with reference to the relevant drawings.

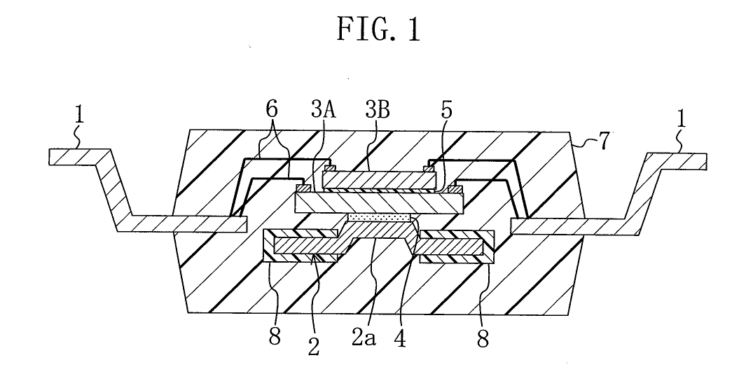

FIG. 1 diagrammatically shows a cross-sectional configuration of a chip-stacked semiconductor device of example Embodiment 1.

As shown in FIG. 1, the semiconductor device of Embodiment 1 includes: a plurality of leads 1 of a lead frame made of a metal; a die pad 2 that is placed in a region surrounded by the plurality of leads 1, is made of a metal, serves also as a heat dissipation plate and has an upset portion 2a in the center upset with respect to its surroundings; and first and second semiconductor chips 3A and 3B attached to the top face of the upset portion 2a of the die pad 2 via an adhesive paste 4 made of a paste resin material.

For the paste resin material, a silver(Ag)-contained epoxy resin or a silver(Ag)-contained polyimide resin may be used.

The first and second semiconductor chips 3A and 3B are attached to each other via an adhesive sheet 5 made of an elastic resin including a thermosetting epoxy component, for example. The semiconductor chips 3A and 3B are connected to the inner ends of the leads 1 via metal wires 6 made of gold (Au).

The die pad 2, the semiconductor chips 3A and 3B, the inner portions of the leads 1 (inner leads) of the lead frame and the metal wires are sealed with a sealing resin material 7 such as an epoxy resin, for example.

The die pad 2, which is made of a member whose plan area is greater than the area of the back face of the first semiconductor chip 3A, can dissipate heat generated by the semiconductor chips 3A and 3B efficiently.

A feature of Embodiment 1 is that the upset portion 2a formed in the center of the die pad 2 has an elevated flat top face, and the top face is smaller in area than the back face of the first semiconductor chip 3A. This reduces the area of the contact portion between the first semiconductor chip 3A and the die pad 2 different in the coefficient of linear expansion from each other. Hence, the plurality of semiconductor chips can be flat as a whole, and also the difference in the volume balance between the upper and lower parts of the sealing resin material 7 can be reduced.

Another feature of Embodiment 1 is that the top, side and back faces of the peripheral portion of the die pad 2 excluding the upset portion 2a are covered with a buffer resin material 8 having a thickness not exceeding the thickness of the upset portion 2a. For the buffer resin material 8, an elastic resin including a thermoplastic resin component, for example, may be used, which will be smaller in elasticity than the sealing resin material 7 after setting. Such a material 8 can therefore absorb the difference between expansion and contraction during temperature cycling exerted on the sealing resin material 7 and the die pad 2.

The buffer resin material 8 may be formed by coating a predetermined region with a molten resin material and then setting the material.

Hence, in this embodiment, it is possible to prevent occurrence of warping of the semiconductor chips due to the difference in the coefficient of linear expansion between materials, which has conventionally been a problem of semiconductor devices having a die pad also serving as the heat dissipation plate, and peeling off or cracking of the sealing resin material 7 during reflowing and temperature cycling.

The above prevention of the heat-causing problems is also effective in the fabrication process for the semiconductor device as follows.

Firstly, the flatness of the top face of the first semiconductor chip 3A can be guaranteed at the time of placing the second semiconductor chip 3B on the first semiconductor chip 3A. Secondly, since the variation in the gap between the first and second semiconductor chips 3A and 3B attached together via the adhesive sheet 5 is reduced, the yield of the wire bonding step at a high temperature improves. Thirdly, warping of the chips, which occurs when the temperature is dropped to set/contract the sealing resin material 7 from a high-temperature state during injection of the sealing resin material 7, can be reduced. Fourthly, the resistance to temperature cycling testing and reflowing improves. In this way, it is possible to seek to improve the reliability of product packaging and product operation from the stage of the fabrication process.

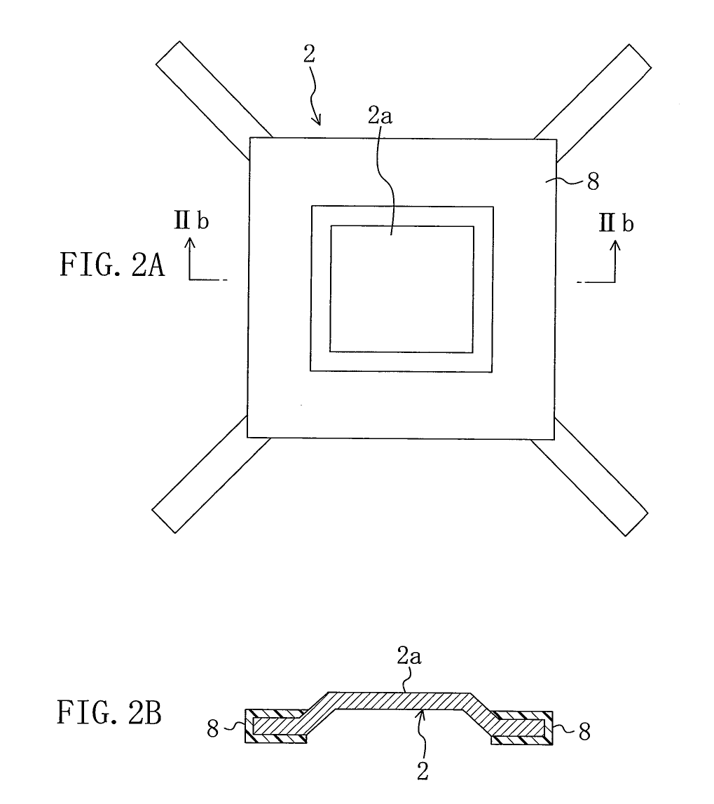

FIG. 2A shows a plan configuration of the die pad 2 having the upset portion 2a in example Embodiment 1, and FIG. 2B shows a cross-sectional configuration taken along line IIb-IIb in FIG. 2A.

In general, when the sealing resin material 7 and the first and second semiconductor chips 3A and 3B are relatively thin, the die pad 2 is dominant for the rigidity of the semiconductor device itself. In this case, pressing under ultrasonic vibration during wire bonding may not be transferred sufficiently due to reduction in the rigidity of the first and second semiconductor chips 3A and 3, for example, and hence a good bonded state of the alloy layers with the wires may not be obtained.

In this embodiment, therefore, the shape of the upset portion 2a of the die pad 2 in plan is made tetragonal or rectangular as shown in FIG. 2A. With this shape, the difference in area between the upset portion 2a and the bottom face of the first semiconductor chip 3A whose shape is normally rectangular is small, and hence the reduction in the rigidity of the semiconductor chips 3A and 3B can be compensated. Also, the difference in the volume balance between the upper and lower parts of the sealing resin material 7 is dominant for the flatness of the entire semiconductor device (the entire package). As such, the flatness can be adjusted by adjusting the height of both the step between the leads 1 and the peripheral portion of the die pad 2 and the step of the upset portion 2a as the inner portion of the die pad 2.

In this embodiment, the outer portions of the leads 1 (outer leads) are bent in a direction apart from the die pad 2 (upward). Alternatively, the outer leads may be bent in a direction close to the die pad 2 (downward).

### First Alteration of Embodiment 1

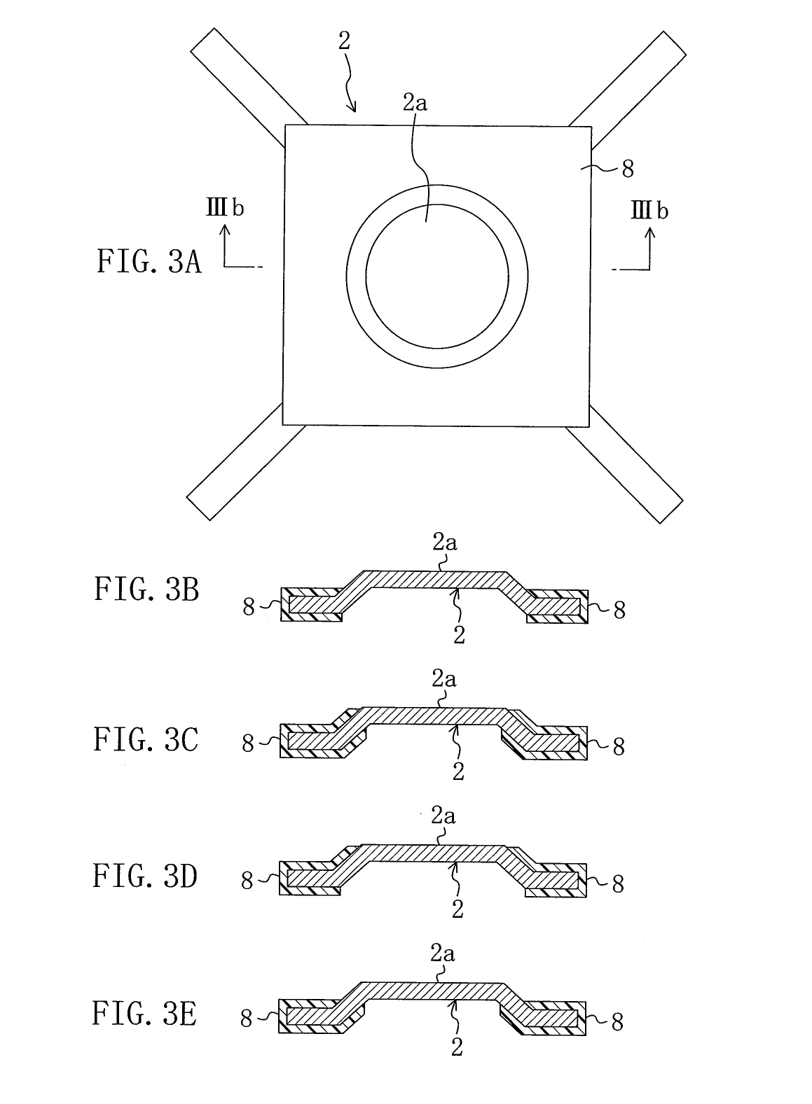

FIG. 3A shows a plan configuration of the die pad 2 having the upset portion 2a in a first alteration of example Embodiment 1, and FIG. 3B shows a cross-sectional configuration taken along line IIIb-IIIb in FIG. 3A.

In general, when the sealing resin material 7 and the first and second semiconductor chips 3A and 3B are relatively thick, the thicknesses of the first and second semiconductor chips 3A and 3B and the sealing resin material 7 are dominant for the rigidity of the semiconductor device itself. In this case, warping does not occur with the stress at the contact portion between the top face of the upset portion 2a as the inner portion of the die pad 2 and the first semiconductor chip 3A attached together via the adhesive paste, which tends to expand or contract during temperature cycling testing and reflowing. Instead, interface fracture may occur with high probability.

In the first alteration, therefore, the shape of the upset portion 2a of the die pad 2 in plan is made circular as shown in FIG. 3A. With this shape, the difference in area between the upset portion 2a and the bottom face of the first semiconductor chip 3A whose shape is normally rectangular is large. Hence, since the area of the contact portion between the die pad 2 and the first semiconductor chip 3A attached together via the adhesive paste 4 that is the stress generation source for interface fracture can be reduced, generation of the stress decreases.

In addition, it will be effective to make the contact area via the adhesive paste 4 further small as long as a predetermined adhesion strength can be guaranteed.

### Second Alteration of Embodiment 1

FIG. 3C shows a cross-sectional configuration of the die pad 2 having the upset portion 2a and the buffer resin material 8 in a second alteration of example Embodiment 1.

As shown in FIG. 3C, the buffer resin material 8 may also cover the upper and lower faces of the inclined portion surrounding the top face of the upset portion 2a of the die pad 2. With this covering, the thermal stress between the materials constituting the semiconductor device is further dispersed, and also the warping of the semiconductor chip is further suppressed. As a result, since peeling off or cracking of the sealing resin material 7 during reflowing is prevented, the flatness between the semiconductor chips further improves. Hence, the reliability can be greatly improved.

### Third Alteration of Embodiment 1

As shown in FIG. 3D, only the upper face of the inclined portion surrounding the top face of the upset portion 2a may be covered with the buffer resin material 8.

### Fourth Alteration of Embodiment 1

As shown in FIG. 3E, only the lower face of the inclined portion surrounding the top face of the upset portion 2a may be covered with the buffer resin material 8.

The second to fourth alterations described above are also applicable to Embodiment 1.

### Fifth Alteration of Embodiment 1

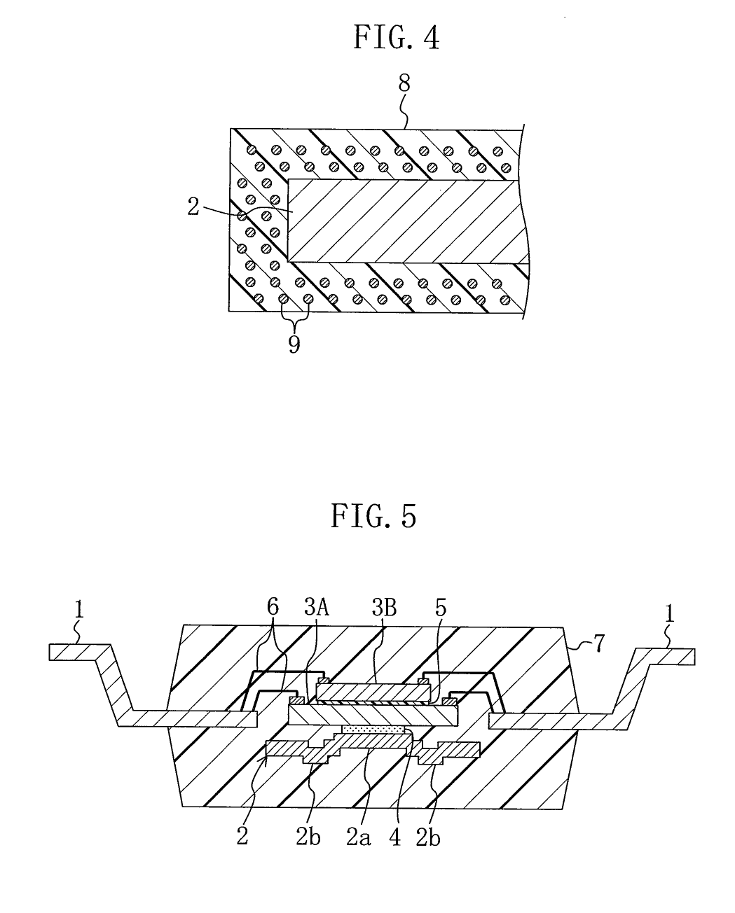

FIG. 4 shows a partial cross-sectional configuration of the peripheral portion of the die pad 2 and the buffer resin material 8 covering the peripheral portion.

In the fifth alteration, grains 9 made of an inorganic material or a metal high in thermal conductivity are added to or mixed in the buffer resin material 8. For the grains 9, silica, alumina, titania, aluminum, copper, silver or the like may be used. The added amount of the grains 9 to the buffer resin material 8 may be roughly in the range of 20% to 60%. Having such grains, the heat dissipation capability of the buffer resin material improves, and thus the reliability of the semiconductor device can be enhanced.

The fifth alternation is applicable to any of Embodiment 1 and the first to fourth alterations.

### Embodiment 2

Example Embodiment 2 will be described with reference to the relevant drawings.

FIG. 5 diagrammatically shows a cross-sectional configuration of a chip-stacked semiconductor device of example Embodiment 2. In FIG. 5, the same components as those in FIG. 1 are denoted by the same reference numerals, and description thereof is omitted in this embodiment.

In Example Embodiment 2, in place of covering the peripheral portion of the die pad 2 other than the upset portion 2a with the buffer resin material 9, a down-set portion 2b is placed to surround the upset portion 2a. The down-set portion 2b is essentially composed of at least one groove protruding from the bottom face (face opposite to the face close to the first semiconductor chip 3A) of the die pad 2. In this embodiment, the down-set portion 2b is formed at a position under the first semiconductor chip 3A.

With placement of the down-set portion 2b, which forms a protrusion on the back face of the die pad 2, a projection/depression anchor composed of the upset portion 2a and the down-set portion 2b is formed against the sealing resin material 7. With this projection/depression anchor effect, the strength improves against the shearing stress and peeling off at the contact face between the die pad 2 also serving as the heat dissipation plate and the sealing resin material 7.

Also, the surface area of the die pad 2 increases by forming the upset section 2a and the down-set section 2b by press shearing, and this further improves heat dissipation.

Moreover, since at least part of the down-set portion 2b is formed at a position overlapping the first semiconductor chip 3A located above, the space is wide between the back face of the first semiconductor chip 3A and the down-set portion 2b. Hence, the amount of the sealing resin material 7 with which the space is filled increases. This improves the elastic bending stress and thus reduces the shearing stress at the contact face between the die pad 2 and the sealing resin material 7. As a result, peeling off at the interface of the sealing resin material 7 with the die pad 2 is further suppressed.

Hence, it is possible to prevent occurrence of warping of the semiconductor chips due to the difference in the coefficient of linear expansion between materials, which has conventionally been a problem of semiconductor devices having a die pad also serving as the dissipation plate, and peeling off or cracking of the sealing resin material 7 during reflowing and temperature cycling.

The above prevention of the heat-causing problems is also effective in the fabrication process for the semiconductor device as follows.

Firstly, the flatness of the top face of the first semiconductor chip 3A can be guaranteed at the time of placing the second semiconductor chip 3B on the first semiconductor chip 3A. Secondly, since the variation in the gap between the first and second semiconductor chips 3A and 3B attached together via the adhesive sheet 5 is reduced, the yield of the wire bonding at a high temperature improves. Thirdly, heat dissipation improves. In this way, it is possible to seek to improve the reliability of product packaging and product operation from the stage of the fabrication process.

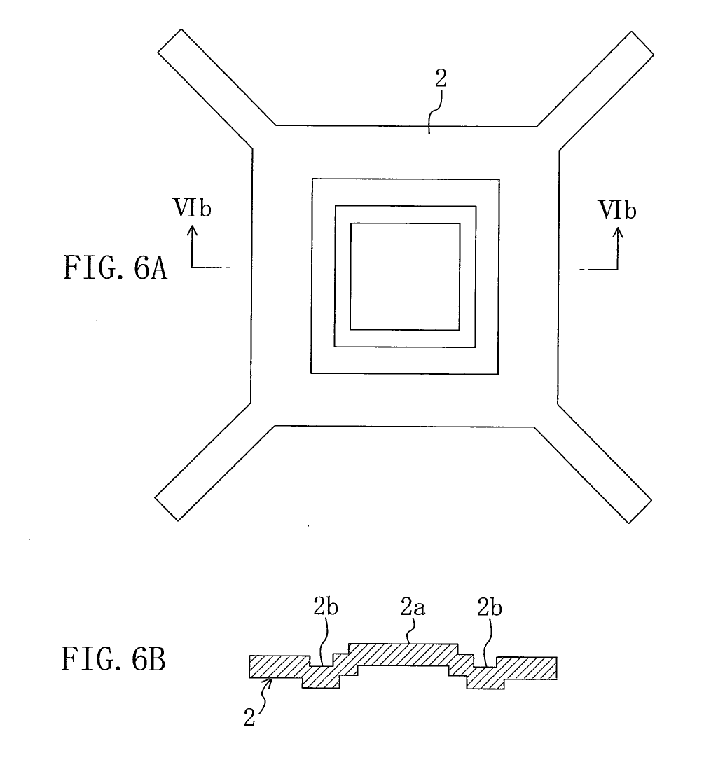

FIG. 6A shows a plan configuration of the die pad 2 having the upset portion 2a and the down-set portion 2b in example Embodiment 2, and FIG. 6B shows a cross-sectional configuration taken along line VIb-VIb in FIG. 6A.

In general, when the sealing resin material 7 and the first and second semiconductor chips 3A and 3B are relatively thin, the die pad 2 is dominant for the rigidity of the semiconductor device itself. In this case, pressing under ultrasonic vibration during wire bonding may not be transferred sufficiently due to reduction in the rigidity of the first and second semiconductor chips 3A and 3B, for example, and hence a good bonded state of the alloy layers with the wires may not be obtained.

In this embodiment, therefore, the shape of the upset portion 2a of the die pad 2 in plan is made tetragonal or rectangular as shown in FIG. 6A. With this shape, the difference in area between the upset portion 2a and the bottom face of the first semiconductor chip 3A whose shape is normally rectangular is small, and hence the reduction in the rigidity of the semiconductor chips 3A and 3B can be compensated. Also, the difference in the volume balance between the upper and lower parts of the sealing resin material 7 is dominant for the flatness of the entire semiconductor device (the entire package). As such, the flatness can be adjusted by adjusting the height of both the step between the leads 1 and the peripheral portion of the die pad 2 and the step of the upset portion 2a as the inner portion of the die pad 2.

Hence, since the area of the contact portion between the first semiconductor chip 3A and the die pad 2 different in the coefficient of linear expansion is small, the flatness of the plurality of semiconductor chips as a whole can be obtained, and also the difference in the volume balance between the upper and lower parts of the sealing resin material 7 can be reduced.

In this embodiment, the outer portions of the leads 1 (outer leads) are bent in a direction apart from the die pad 2 (upward). Alternatively, the outer leads may be bent in a direction close to the die pad 2 (downward).

### Alteration of Embodiment 2

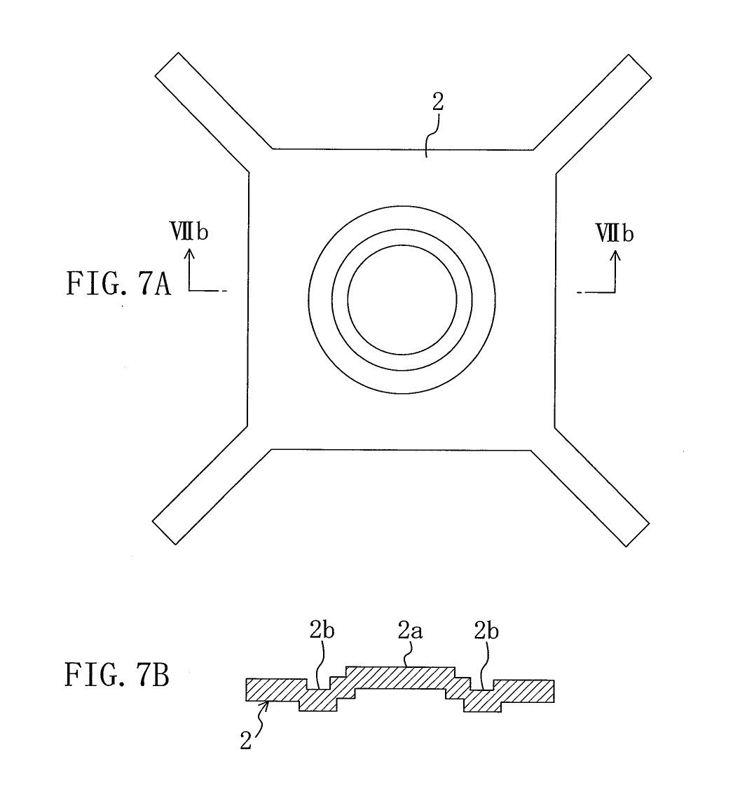

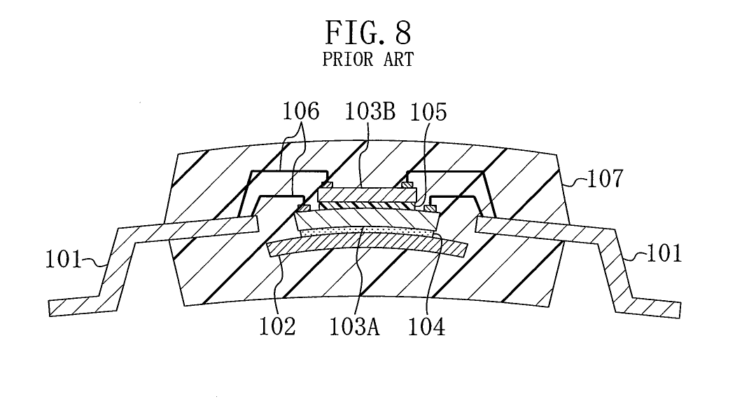

FIG. 7A shows a plan configuration of the die pad 2 having the upset portion 2a and the down-set portion 2b in an alteration of example Embodiment 2, and FIG. 3B shows a cross-sectional configuration taken along line VIIb-VIIb in FIG. 7A.

In general, when the sealing resin material 7 and the first and second semiconductor chips 3A and 3B are relatively thick, the thicknesses of the first and second semiconductor chips 3A and 3B and the sealing resin material 7 are dominant for the rigidity of the semiconductor device itself. In this case, warping does not occur with the stress at the contact portion between the top face of the upset portion 2a as the inner portion of the die pad 2 and the first semiconductor chip 3A attached together via the adhesive paste 4, which tends to expand or contract during temperature cycling testing and reflowing. Instead, interface fracture may occur with high probability.

In this alteration, therefore, the shape of the upset portion 2a of the die pad 2 in plan is made circular as shown in FIG. 7A. With this shape, the difference in area between the upset portion 2a and the bottom face of the first semiconductor chip 3A whose shape is normally rectangular is large. Hence, since the area of the contact portion between the die pad 2 and the first semiconductor chip 3A attached together via the adhesive paste 4 that is the stress generation source for interface fracture can be reduced, generation of the stress decreases.

It will be effective to make the contact area via the adhesive paste 4 further small as long as a predetermined adhesion strength can be guaranteed.

Hence, since the area of the contact portion between the first semiconductor chip 3A and the die pad 2 different in the coefficient of linear expansion is small, the flatness of the plurality of semiconductor chips as a whole can be obtained, and also the difference in the volume balance between the upper and lower parts of the sealing resin material 7 can be reduced.

Note that although the case of stacking two semiconductor chips one on the other was described in example Embodiments 1 and 2 and their alterations, the present disclosure is also applicable to cases of stacking three or more semiconductor chips one on another.

As described above, in the semiconductor device of the present disclosure, packaged with a sealing resin material, the thermal stress between component materials is dispersed and the warping of semiconductor chips is suppressed. As a result, the flatness between the chips improves, and hence the reliability can be improved. Accordingly, the present disclosure is useful for semiconductor devices having a plurality of chips sealed therein.

What is claimed is:

1. A semiconductor device comprising:
a semiconductor chip;
a die pad for holding the semiconductor chip;
a lead; and
a sealing resin material for sealing the semiconductor chip, the die pad and an inner portion of the lead,
wherein the die pad has an upset portion protruding upward to form a flat face smaller in area than the semiconductor chip, and
the portion of the die pad excluding the upset portion is covered with a buffer resin material smaller in elasticity than the sealing resin material.

2. The semiconductor device of claim 1, wherein the semiconductor chip includes a plurality of semiconductor chips attached to each other.

3. The semiconductor device of claim 1, wherein the upset portion and the semiconductor chip are attached to each other with an adhesive, and
the adhesive is a paste resin material.

4. The semiconductor device of claim 1, wherein the plan area of the die pad is greater than the plan area of the semiconductor chip.

5. The semiconductor device of claim 1, wherein the shape of the upset portion in plan is tetragonal.

6. The semiconductor device of claim 1, wherein the shape of the upset portion in plan is circular.

7. The semiconductor device of claim 1, wherein the buffer resin material includes grains made of an inorganic material or a metal high in thermal conductivity added therein.

8. A semiconductor device comprising:
a semiconductor chip;
a die pad for holding the semiconductor chip;
a lead; and
a sealing resin material for sealing the semiconductor chip, the die pad and an inner portion of the lead,
wherein the die pad has an upset portion protruding upward to form a flat face smaller in area than the semiconductor chip and a down-set portion essentially composed of at least one groove protruding downward from the bottom face of the die pad.

9. The semiconductor device of claim 8, wherein the down-set portion of the die pad is formed at a position under the semiconductor chip.

10. The semiconductor device of claim 8, wherein the upset portion and the down-set portion are formed by press shearing and have a side face vertical to the main face of the die pad.

11. The semiconductor device of claim 8, wherein the semiconductor chip includes a plurality of semiconductor chips attached to each other.

12. The semiconductor device of claim 8, wherein the upset portion and the semiconductor chip are attached to each other with an adhesive, and
the adhesive is a paste resin material.

13. The semiconductor device of claim 8, wherein the plan area of the die pad is greater than the plan area of the semiconductor chip.

14. The semiconductor device of claim 8, wherein the shape of the upset portion in plan is tetragonal.

15. The semiconductor device of claim 8, wherein the shape of the upset portion in plan is circular.
